(19) United States
(12) Patent Application Publication
(10) Pub. No.: US 2019/0207041 A1
(43) Pub. Date: Jul. 4, 2019

(54) SOLAR CELLS HAVING DIFFERENTIATED P-TYPE AND N-TYPE ARCHITECTURES FABRICATED USING AN ETCH PASTE

(71) Applicant: SUNPOWER CORPORATION, San Jose, CA (US)

(72) Inventors: Seung Bum RIM, Palo Alto, CA (US); David D. SMITH, Campbell, CA (US)

(21) Appl. No.: 15/859,066

(22) Filed: Dec. 29, 2017

(51) Int. Cl. H01L 31/0224; H01L 31/028; H01L 31/0368; H01L 31/0236; H01L 31/18

(52) U.S. Cl. CPC H01L 31/022425; H01L 31/028; H01L 31/1804; H01L 31/02363; H01L 31/03682

(57) ABSTRACT

Methods of fabricating solar cell emitter regions with differentiated P-type and N-type region architectures fabricated using an etch paste, and the resulting solar cells, are described herein. In an example, a solar cell includes a plurality of P-type polycrystalline silicon regions is disposed on a first thin dielectric layer disposed on a back surface of an N-type semiconductor substrate. A plurality of N-type polycrystalline silicon regions is disposed on a second thin dielectric layer disposed in a corresponding one of a plurality of trenches interleaving the plurality of P-type polycrystalline silicon regions in the back surface of the N-type semiconductor substrate. A plurality of conductive contact structures is electrically connected to the P-type polycrystalline silicon regions and the N-type polycrystalline silicon regions. An etch paste residue is between at least one of the plurality of conductive contact structures and a corresponding one of the plurality of P-type polycrystalline silicon regions.

### TECHNICAL FIELD

Embodiments of the present disclosure are in the field of renewable energy and, in particular, solar cells with solar cell emitter regions having differentiated P-type and N-type regions architectures fabricated using an etch paste.

### BACKGROUND

Photovoltaic cells, commonly known as solar cells, are well known devices for direct conversion of solar radiation into electrical energy. Generally, solar cells are fabricated on a semiconductor wafer or substrate using semiconductor processing techniques to form a p-n junction near a surface of the substrate. Solar radiation impinging on the surface of, and entering into, the substrate creates electron and hole pairs in the bulk of the substrate. The electron and hole pairs migrate to p-doped and n-doped regions in the substrate, thereby generating a voltage differential between the doped regions. The doped regions are connected to conductive regions on the solar cell to direct an electrical current from the cell to an external circuit coupled thereto.

### BRIEF DESCRIPTION OF THE DRAWINGS

FIG. 1 is a flowchart listing operations in a method of fabricating a solar cell, in accordance with an embodiment of the present disclosure.

FIGS. 2A-2I illustrate cross-sectional views of various stages in the fabrication of a solar cell, in accordance with an embodiment of the present disclosure.

FIG. 3 illustrates a cross-sectional view of a portion of a back contact solar cell, in accordance with an embodiment of the present disclosure.

FIG. 4 illustrates a cross-sectional view of a portion of a back contact solar cell, in accordance with another embodiment of the present disclosure.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

Terminology. The following paragraphs provide definitions and/or context for terms found in this disclosure (including the appended claims):

“Comprising.” This term is open-ended. As used in the appended claims, this term does not foreclose additional structure or steps.

“Configured To.” Various units or components may be described or claimed as “configured to” perform a task or tasks. In such contexts, “configured to” is used to connote structure by indicating that the units/components include structure that performs those task or tasks during operation. As such, the unit/component can be said to be configured to perform the task even when the specified unit/component is not currently operational (e.g., is not on/active). Reciting that a unit/circuit/component is “configured to” perform one or more tasks is expressly intended not to invoke 35 U.S.C. § 112, sixth paragraph, for that unit/component.

“First,” “Second,” etc. As used herein, these terms are used as labels for nouns that they precede, and do not imply any type of ordering (e.g., spatial, temporal, logical, etc.). For example, reference to a “first” solar cell does not necessarily imply that this solar cell is the first solar cell in a sequence; instead the term “first” is used to differentiate this solar cell from another solar cell (e.g., a “second” solar cell).

“Coupled”—The following description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically.

In addition, certain terminology may also be used in the following description for the purpose of reference only, and thus are not intended to be limiting. For example, terms such as “upper”, “lower”, “above”, and “below” refer to directions in the drawings to which reference is made. Terms such as “front”, “back”, “rear”, “side”, “outboard”, and “inboard” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

“Inhibit”—As used herein, inhibit is used to describe a reducing or minimizing effect. When a component or feature is described as inhibiting an action, motion, or condition it may completely prevent the result or outcome or future state completely. Additionally, “inhibit” can also refer to a reduction or lessening of the outcome, performance, and/or effect which might otherwise occur. Accordingly, when a component, element, or feature is referred to as inhibiting a result or state, it need not completely prevent or eliminate the result or state.

Efficiency is an important characteristic of a solar cell as it is directly related to the capability of the solar cell to generate power. Likewise, efficiency in producing solar cells is directly related to the cost effectiveness of such solar cells. Accordingly, techniques for increasing the efficiency of solar cells, or techniques for increasing the efficiency in the manufacture of solar cells, are generally desirable. Some embodiments of the present disclosure allow for increased solar cell manufacture efficiency by providing novel processes for fabricating solar cell structures. Some embodiments of the present disclosure allow for increased solar cell efficiency by providing novel solar cell structures.

Methods of fabricating solar cell emitter regions with differentiated P-type and N-type region architectures fabricated using an etch paste, and the resulting solar cells, are described herein. In the following description, numerous specific details are set forth, such as specific process flow operations, in order to provide a thorough understanding of embodiments of the present disclosure. It will be apparent to one skilled in the art that embodiments of the present disclosure may be practiced without these specific details. In other instances, well-known fabrication techniques, such as lithography and patterning techniques, are not described in detail in order to not unnecessarily obscure embodiments of the present disclosure. Furthermore, it is to be appreciated that the various embodiments shown in the figures are illustrative representations and are not necessarily drawn to scale.

Disclosed herein are methods of fabricating solar cells. In one embodiment, a method of fabricating a solar cell includes forming a first polycrystalline silicon layer above a substrate. An insulating cap is formed on the first polycrystalline silicon layer. A second polycrystalline silicon layer is formed on the insulating cap. An insulating layer is formed on the second polycrystalline silicon layer. A portion of the insulating layer and a portion of the second polycrystalline silicon layer are laser ablated to form an opening exposing a portion of the insulating cap on the first polycrystalline silicon layer. The exposed portion of the insulating cap is removed with an etch paste to extend the opening and expose a portion of the first polycrystalline silicon layer. Subsequent to removing the exposed portion of the insulating cap with the etch paste, the extended opening is cleaned by removing residual etch paste.

In another embodiment, a method of fabricating a solar cell includes forming a plurality of P-type polycrystalline silicon regions on a first thin dielectric layer on a back surface of an N-type semiconductor substrate. The N-type semiconductor substrate has a light-receiving surface opposite the back surface. The method further includes forming an insulating cap on the P-type polycrystalline silicon regions. The method further includes forming a plurality of N-type polycrystalline silicon regions on a second thin dielectric layer formed in a corresponding one of a plurality of trenches interleaving the plurality of P-type polycrystalline silicon regions in the back surface of the P-type semiconductor substrate. A portion of the plurality of N-type polycrystalline silicon regions overlaps the insulating cap on the P-type polycrystalline silicon regions. The method further includes forming an insulating layer on the plurality of N-type polycrystalline silicon regions. The method further includes laser ablating a portion of the insulating layer and a portion of the plurality of N-type polycrystalline silicon regions to expose a portion of the insulating cap on the P-type polycrystalline silicon regions. The method further includes removing the exposed portions of the insulating cap with an etch paste to expose a portion of the P-type polycrystalline silicon regions. The method further includes forming a plurality of conductive contact structures electrically connected to the P-type polycrystalline silicon regions and the N-type polycrystalline silicon regions.

Also disclosed herein are solar cells. In one embodiment, a solar cell includes an N-type semiconductor substrate having a light-receiving surface and a back surface. A plurality of P-type polycrystalline silicon regions is disposed on a first thin dielectric layer disposed on the back surface of the N-type semiconductor substrate. A plurality of N-type polycrystalline silicon regions is disposed on a second thin dielectric layer disposed in a corresponding one of a plurality of trenches interleaving the plurality of P-type polycrystalline silicon regions in the back surface of the N-type semiconductor substrate. A plurality of conductive contact structures is electrically connected to the P-type polycrystalline silicon regions and the N-type polycrystalline silicon regions. An etch paste residue is between at least one of the plurality of conductive contact structures and a corresponding one of the plurality of P-type polycrystalline silicon regions.

One or more embodiments are directed to printed contacts for hybrid solar cells. For example, embodiments may involve the use of a printable paste, such as a hydrofluoric acid (HF) based paste or a phosphoric acid (H₃PO₄) based paste to form contacts for a differentiated or hybrid architecture. Advantages of implementing one or more embodiments described herein may include the ability to achieve low or no laser damage, reducing shunt risks, and the opportunity to incorporate a relatively thinner polycrystalline silicon layer.

To provide context, hybrid or differentiated architectures promise fewer process operations and simpler architecture while providing potential for high efficiencies. However, there are a few technical limitations for implementation in current development, one of which is the conductive contact process. For example, high power laser contact processes may otherwise limit relative thinning of polycrystalline silicon thickness.

In accordance with an embodiment of the present disclosure, a printable hydrofluoric acid (HF) based paste or a phosphoric acid (H₃PO₄) based paste is used in place of full wet etching for forming contact openings. Processing may involve opening a top polycrystalline silicon layer with a laser process and then printing an HF paste to clear dielectric underneath the polycrystalline silicon layer. Since the HF paste may not lead to wrap around at the edge of a wafer of a solar cell, a relatively thicker polycrystalline silicon layer may no longer be needed. That is, thinner polycrystalline silicon fabrication using shorter process times may be achievable. Also, shunting risk may be reduced since HF pastes may be printed as opposed to applied generally. Furthermore, an HF paste may be used to clear native oxide which may be grown over a second polycrystalline silicon layer without overlay.

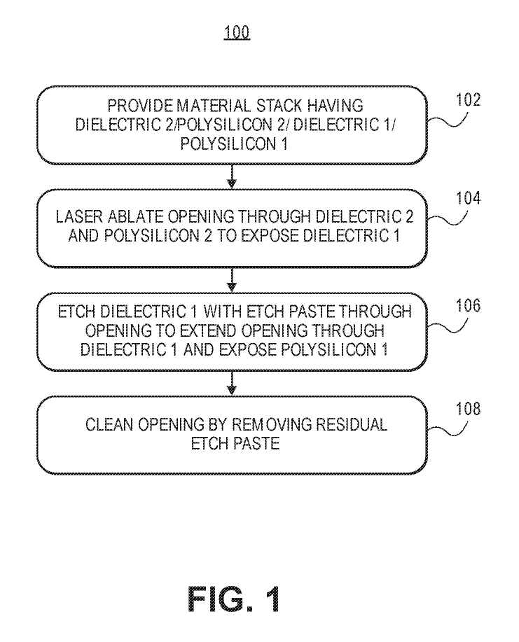

In an exemplary processing scheme, FIG. 1 is a flowchart 100 listing operations in a method of fabricating a solar cell, in accordance with an embodiment of the present disclosure.

Referring to operation 102 of the flowchart 100 of FIG. 1, a method of fabricating a solar cell includes forming a first polycrystalline silicon layer (POLYSILICON 1) above a substrate. An insulating cap (DIELECTRIC 1) is formed on the first polycrystalline silicon layer (POLYSILICON 1). In an embodiment, the first polycrystalline silicon layer (POLYSILICON 1) has a thickness of approximately 200-500 Angstroms. In another embodiment, the first polycrystalline silicon layer (POLYSILICON 1) has a thickness of approximately 1000-3000 Angstroms. In an embodiment, the insulating cap (DIELECTRIC 1) has a thickness of approximately 1800-2000 Angstroms.

Referring again to operation 102 of flowchart 100, a second polycrystalline silicon layer (POLYSILICON 2) is formed on the insulating cap (DIELECTRIC 1). An insulating layer (DIELECTRIC 2) is formed on the second polycrystalline silicon layer (POLYSILICON 2).

Referring to operation 104 of the flowchart 100 of FIG. 1, a portion of the insulating layer (DIELECTRIC 2) and a portion of the second polycrystalline silicon layer (POLYSILICON 2) are laser ablated to form an opening exposing a portion of the insulating cap (DIELECTRIC 1) on the first polycrystalline silicon layer (POLYSILICON 1). In an embodiment, the second polycrystalline silicon layer (POLYSILICON 2) has a thickness of approximately 200-500 Angstroms, and the insulating layer (DIELECTRIC 2) has a thickness of approximately 500-2000 Angstroms. In one such embodiment, laser ablating the portion of the insulating layer (DIELECTRIC 2) and the portion of the second polycrystalline silicon layer (POLYSILICON 2) includes laser ablating with a green laser.

Referring to operation 106 of the flowchart 100 of FIG. 1, the exposed portion of the insulating cap (DIELECTRIC 1) is removed with an etch paste to extend the opening and expose a portion of the first polycrystalline silicon layer (POLYSILICON 1). In an embodiment, removing the exposed portions of the insulating cap (DIELECTRIC 1) with the etch paste includes using a hydrofluoric acid (HF) based etch paste or a phosphoric acid (H₃PO₄) based paste.

Referring to operation 108 of the flowchart 100 of FIG. 1, subsequent to removing the exposed portion of the insulating cap (DIELECTRIC 1) with the etch paste, the extended opening is cleaned by removing residual etch paste. In an embodiment, the etch paste is a hydrofluoric acid (HF) based etch paste or a phosphoric acid (H₃PO₄) based paste, and the residual etch paste is removed using an aqueous based rinse. In an embodiment, subsequent processing includes forming a conductive contact structure in the extended opening. The conductive contact structure is electrically connected to the first polycrystalline silicon layer (POLYSILICON 1).

One or more embodiments described herein are directed to forming P+ and N+ polysilicon emitter regions for a solar cell where the respective structures of the P+ and N+ polysilicon emitter regions are different from one another. Such an approach can be implemented to simplify a solar cell fabrication process. Furthermore, the resulting structure may provide a lower breakdown voltage and lower power losses associated as compared with other solar cell architectures.

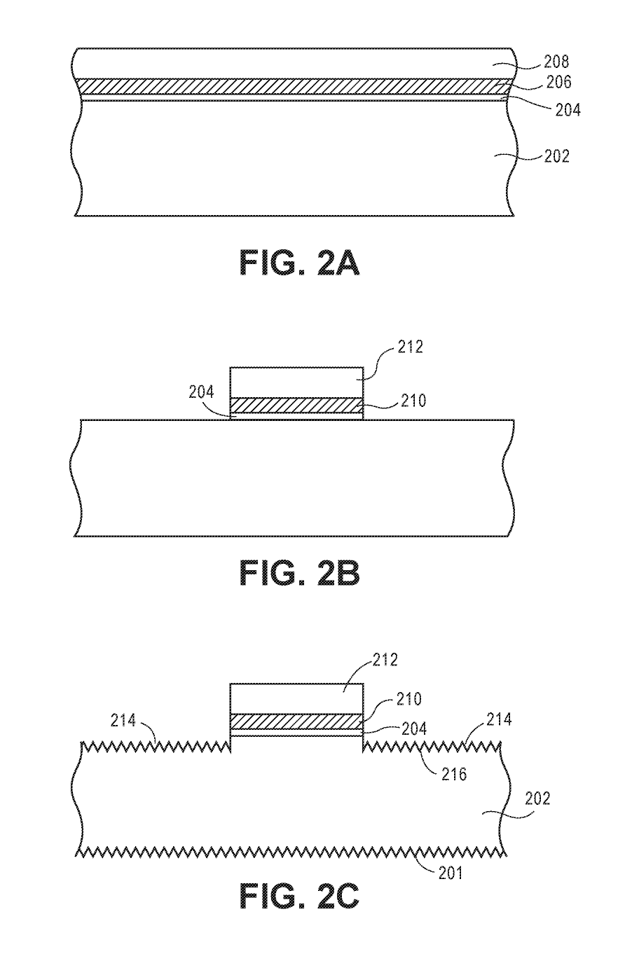

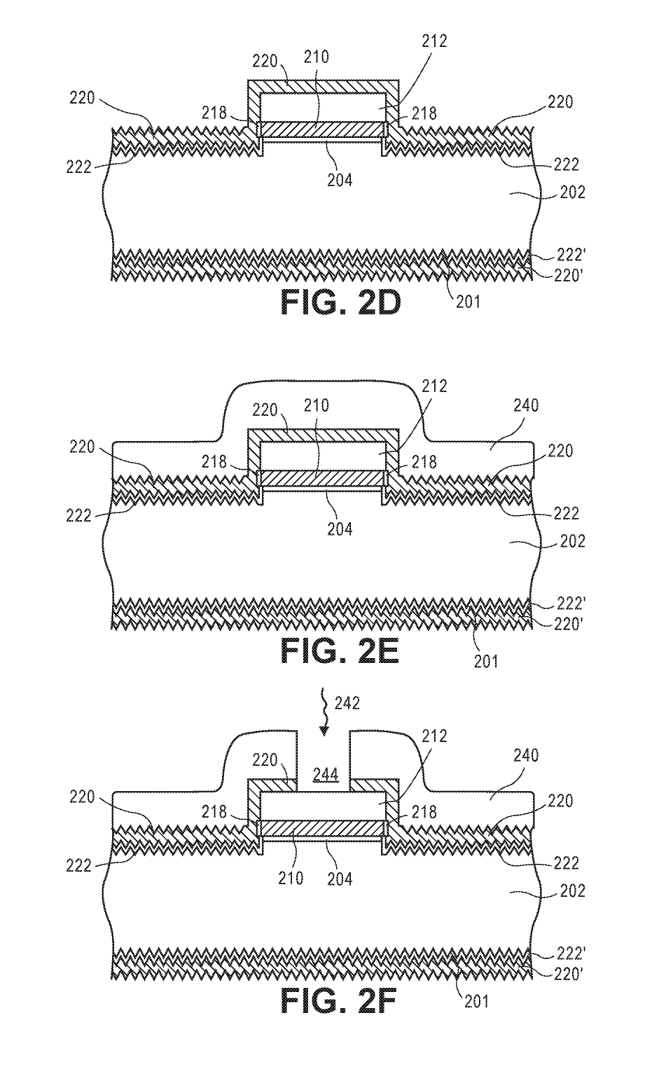

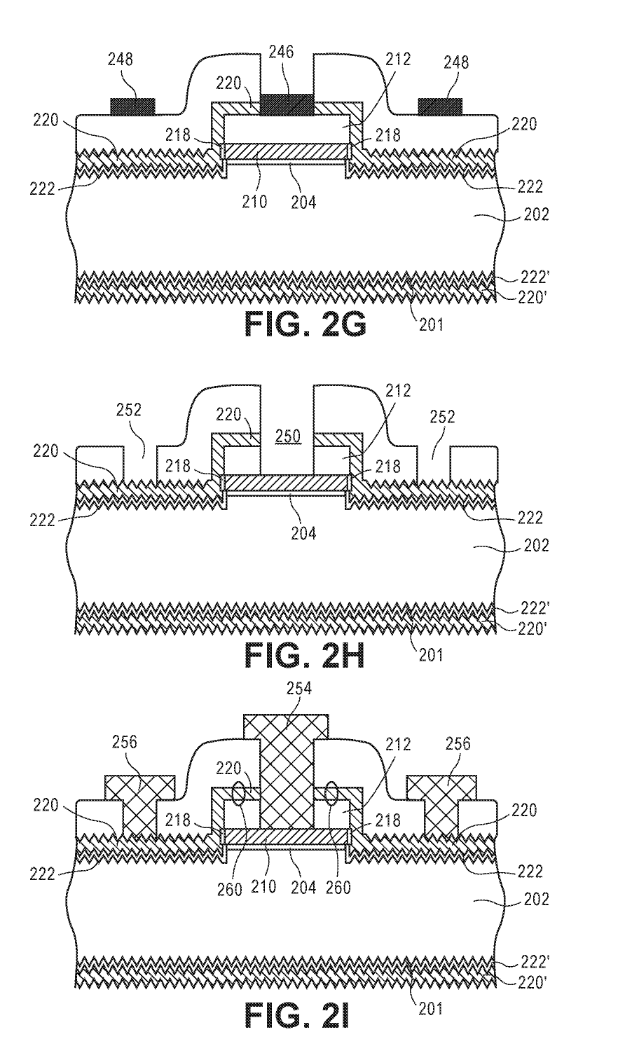

In another exemplary processing scheme, FIGS. 2A-2I illustrate cross-sectional views of various stages in the fabrication of a solar cell, in accordance with an embodiment of the present disclosure.

Referring to FIG. 2A, a method of fabricating alternating N-type and P-type emitter regions of a solar cell involves forming a P-type silicon layer 206 on a first thin dielectric layer 204 formed on a back surface of a substrate 202.

In an embodiment, the substrate 202 is a monocrystalline silicon substrate, such as a bulk single crystalline N-type doped silicon substrate. It is to be appreciated, however, that substrate 202 may be a layer, such as a multi-crystalline silicon layer, disposed on a global solar cell substrate. In an embodiment, the first thin dielectric layer 204 is a thin oxide layer such as a tunnel dielectric silicon oxide layer having a thickness of approximately 2 nanometers or less.

In an embodiment, the P-type silicon layer 206 is a polycrystalline silicon layer that is doped to have P-type conductivity type either through in situ doping during deposition, post deposition implanting, post deposition solid state diffusion, or a combination thereof In another embodiment the P-type silicon layer 206 is an amorphous silicon layer such as a hydrogenated silicon layer represented by a—Si:H which is implanted or diffused with P-type dopants subsequent to deposition of the amorphous silicon layer. In one such embodiment, P-type silicon layer 206 is subsequently annealed (at least at some subsequent stage of the process flow) to ultimately form a P-type polycrystalline silicon layer. In an embodiment, for either a polycrystalline silicon layer or an amorphous silicon layer, if post deposition implantation is performed, the implanting is performed by using ion beam implantation or plasma immersion implantation. In one such embodiment, a shadow mask is used for the implanting. In another embodiment, for either a polycrystalline silicon layer or an amorphous silicon layer, if post deposition diffusion is performed, a solid state doping layer such as borosilicate glass (BSG) is used either as a sacrificial layer or permanent layer deposited on the polycrystalline silicon layer or amorphous silicon layer. In a specific embodiment, the P-type dopants are boron impurity atoms. In an embodiment, the P-type silicon layer 206 has a thickness of approximately 200-500 Angstroms. In another embodiment, the P-type silicon layer 206 has a thickness of approximately 1000-3000 Angstroms.

Referring again to FIG. 2A, an insulating layer 208 is formed on the P-type silicon layer 206. In an embodiment the insulating layer 208 is or includes silicon oxide or silicon dioxide. In an embodiment, the insulating layer 208 has a thickness of approximately 1800-2000 Angstroms.

Referring to FIG. 2B, the insulating layer 208 and the P-type silicon layer 206 are patterned to form a P-type silicon region 210 having an insulating cap 212 thereon. In an embodiment, a lithographic or screen print masking and subsequent etch process is used to pattern the insulating layer 208 and the P-type silicon layer 206. In another embodiment, a laser ablation process (e.g., direct write) is used to pattern the insulating layer 208 and the P-type silicon layer 206. In either case, in one embodiment, the first thin dielectric layer 204 is also patterned in the process, as is depicted in FIG. 2B.

Referring to FIG. 2C, optionally, trenches or recesses 214 may be formed in the substrate 202 during (or subsequent to) the patterning of the insulating layer 208 and the P-type silicon layer 206. Furthermore, in one embodiment, the surfaces 216 of the recesses 214 are texturized. In a same or similar process, a light receiving surface 201 of the substrate 202 may also be texturized, as is depicted in FIG. 2C. In an embodiment, a hydroxide-based wet etchant is used to form at least a portion of the recesses 214 and/or to texturize exposed portions of the substrate 202. In an embodiment, each of the trenches has a depth approximately in the range of 0.1-3 microns from the back surface and into the substrate 202.

It is to be appreciated that the texturizing of the back surface and even the recess formation may be omitted from the process flow. It is also to be appreciated that the timing of the front side texturizing, is applied, can be performed at different locations along the process flow, e.g., prior to back side emitter region formation, subsequent to back side emitter region formation, or as part of the process of back side emitter region formation. In one such embodiment, the front side texturizing is performed prior to back side emitter region formation, and the texturized front side is protected by a sacrificial or permanent capping layer during subsequent back side emitter region formation. It is also to be appreciated that, whether on the front side or back side, a texturized surface may be one which has a regular or an irregular shaped surface for scattering incoming light, decreasing the amount of light reflected off of the light-receiving and/or exposed surfaces of the solar cell.

Referring to FIG. 2D, a second thin dielectric layer 218 is formed on exposed sides of the P-type silicon region 210. In an embodiment, the second thin dielectric layer 218 is formed in an oxidation process and is a thin oxide layer such as a tunnel dielectric silicon oxide layer having a thickness of approximately 2 nanometers or less. In another embodiment, the second thin dielectric layer 204 is formed in a deposition process and is a thin silicon nitride layer or silicon oxynitride layer.

Referring again to FIG. 2D, an N-type silicon layer 220 is formed on a third thin dielectric layer 222 formed on the back surface of the substrate 202, and on the second thin dielectric layer 218 and the insulating cap 212 of the P-type silicon region 210. Corresponding thin dielectric layer 222′ may also be formed on the light-receiving surface 201 of the substrate 202, in a same or similar process operations, as is depicted in FIG. 2D.

Additionally, an N-type silicon layer 220′ may also be formed on the light-receiving surface 201 of the substrate 202, as is depicted in FIG. 2D. In one such embodiment, the N-type silicon layer 220′ is formed using an initially undoped or lightly doped silicon layer formed on the front side at the same time as forming a corresponding initially undoped or lightly doped silicon layer ultimately used to form the N-type silicon layer 220. The N-type silicon layer 220′ is then formed by subsequent N-type doping of the initially undoped or lightly doped silicon layer. Furthermore, although not depicted, an ARC layer may be formed on the corresponding N-type silicon layer 220′.

In an embodiment, the third thin dielectric layer 218 is formed in an oxidation process and is a thin oxide layer such as a tunnel dielectric silicon oxide layer having a thickness of approximately 2 nanometers or less. In an embodiment, the N-type silicon layer 220 is a polycrystalline silicon layer that is doped to have N-type conductivity type either through in situ doping, post deposition implanting, post deposition solid state diffusion, or a combination thereof. In another embodiment the N-type silicon layer 220 is an amorphous silicon layer such as a hydrogenated silicon layer represented by a—Si:H which is implanted or diffused with N-type dopants subsequent to deposition of the amorphous silicon layer. In one such embodiment, the N-type silicon layer 220 is subsequently annealed (at least at some subsequent stage of the process flow) to ultimately form an N-type polycrystalline silicon layer. In an embodiment, for either a polycrystalline silicon layer or an amorphous silicon layer, if post deposition implantation is performed, the implanting is performed by using ion beam implantation or plasma immersion implantation. In one such embodiment, a shadow mask is used for the implanting. In another embodiment, for either a polycrystalline silicon layer or an amorphous silicon layer, if post deposition diffusion is performed, a solid state doping layer such as phosphosilicate glass (PSG) is used either as a sacrificial layer or permanent layer deposited on the polycrystalline silicon layer or amorphous silicon layer. In a specific embodiment, the N-type dopants are phosphorous or arsenic impurity atoms.

In an embodiment, the N-type silicon layer 220 has a thickness of approximately 200-500 Angstroms. In an embodiment, the N-type silicon layer 220 has a thickness approximately the same as the thickness of the P-type silicon layer 206. In an embodiment, the P-type silicon region 210 is formed using an in situ doping chemical vapor deposition (CVD) process, and the N-type silicon layer 220 is formed using a solid-state doping process.

Referring to FIG. 2E, an insulating layer 240 is formed on the structure of FIG. 2D. In an embodiment, the insulating layer 240 has a thickness of approximately 500-2000 Angstroms. In an embodiment, the insulating layer 240 is or includes silicon oxide or silicon dioxide.

Referring to FIG. 2F, a portion of the insulating layer 240 and a portion of the N-type silicon layer 220 are laser ablated 242 to form a contact opening 244 exposing a portion of the insulating cap 212 on the P-type silicon region 210. In an embodiment, the laser ablation 242 is performed using a green laser. In an embodiment, the insulating cap 212 protects the P-type silicon region 210 during the laser ablation 242.

Referring to FIG. 2G, an etch paste portion 246 is provided in the contact opening 244. In an embodiment, the etch paste is a hydrofluoric acid (HF) based etch paste or a phosphoric acid (H₃PO₄) based paste. In an embodiment, additional etch paste portions 248 are formed on the insulating layer 240 over the N-type silicon layer 220, as is depicted.

Referring to FIG. 2H, a portion of the insulating cap 212 is removed by the etch paste in the location of etch paste portion 246 to expose a portion of the P-type silicon region 210. In an embodiment, portions of the insulating layer 240 are removed by the etch paste in the locations of etch paste portions 248 to expose portions of the N-type silicon layer 220. In an embodiment, the etch paste portions 246 and 248 are then removed by a cleaning process, such as an aqueous cleaning process, to form openings 250 and 252, respectively.

Referring to FIG. 2I, conductive contacts 254 and 256 are formed in openings 250 and 252, respectively, for the P-type silicon region 210 and the N-type silicon regions 220, respectively. The fabrication of the conductive contacts 254 and 256 can involve use of one or more sputtered, plated or bonded conductive layers. In an embodiment, the conductive contacts are formed by first forming a metal seed layer on the exposed portions of the P-type silicon region 210 and on the N-type silicon regions 220. In an embodiment, a mask is first formed to expose only select portions of the P-type silicon region 210 and the N-type silicon regions 220 in order to direct the metal seed layer formation to restricted locations. It is to be appreciated that portions 260 of the N-type silicon regions 220 may be removed at earlier, at the same, or on a subsequent processing operation in order to electrically isolate the P-type silicon region 210 from the N-type silicon regions 220.

In an embodiment, in the case that a metal seed layer is used, the metal seed layer is an aluminum-based metal seed layer. In an embodiment, the metal seed layer includes a layer having a thickness approximately in the range of 0.05 to 20 microns and includes aluminum in an amount greater than approximately 90 atomic %. In an embodiment, the metal seed layer is deposited as a blanket layer which is later patterned, e.g., thus using a deposition, lithographic, and etch approach. In another embodiment, the metal seed layer is deposited as patterned layer. In one such embodiment, the patterned metal seed layer is deposited by printing the patterned metal seed layer.

In an embodiment, contact 254 and 256 formation further includes forming a metal layer by plating on a metal seed layer such as described above to form conductive contacts for the P-type silicon region 210 and the N-type silicon regions 220. In an embodiment, the metal layer is a copper layer. Accordingly, in an embodiment, the conductive contacts 254 and 256 are formed by first forming a metal seed layer and then performing an electroplating process.

In another embodiment, the conductive contacts 254 and 256 are formed by printing a paste. The paste may be composed of a solvent and the aluminum/silicon (Al/Si) alloy particles. A subsequent electroplating or electroless-plating process may then be performed. The paste may be formed in addition to, or in place of, a metal seed layer described above.

In another embodiment, the conductive contacts 254 and 256 are formed by first forming a metal seed layer and then adhering a metal foil layer to the metal seed layer. In one such embodiment, the metal foil is an aluminum (Al) foil having a thickness approximately in the range of 5-100 microns. In one embodiment, the Al foil is an aluminum alloy foil including aluminum and second element such as, but not limited to, copper, manganese, silicon, magnesium, zinc, tin, lithium, or combinations thereof. In one embodiment, the Al foil is a temper grade foil such as, but not limited to, F-grade (as fabricated), O-grade (full soft), H-grade (strain hardened) or T-grade (heat treated). In one embodiment, the aluminum foil is an anodized aluminum foil. In an embodiment, the metal foil is welded to a metal seed layer. The metal foil may subsequently be patterned, e.g., by laser ablation and/or etching.

It is to be appreciated that one or more processes described above may be implemented to fabricate a solar cell. The above described processes may be implemented in their entirety or portions of the one or more processes described above may be implemented to fabricate a solar cell.

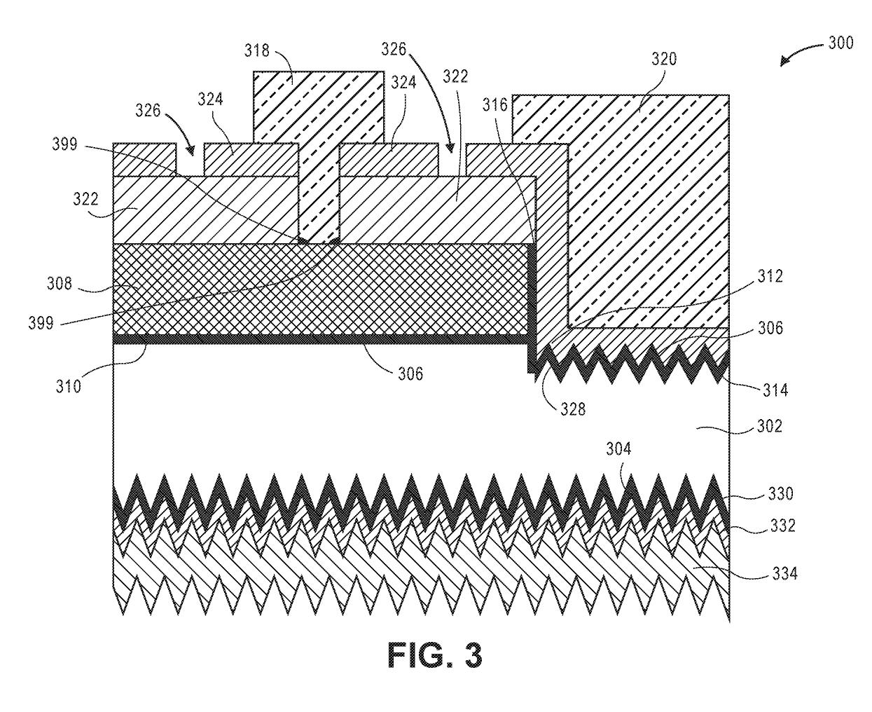

As a first exemplary solar cell, FIG. 3 illustrates a cross-sectional view of a portion of a back contact solar cell 300, in accordance with an embodiment of the present disclosure.

The solar cell 300 includes a substrate 302 having a light-receiving surface 304 and a back surface 306. A P-type polycrystalline silicon emitter region 308 is disposed on a first thin dielectric layer 310 disposed on the back surface 306 of the substrate 302. An N-type polycrystalline silicon emitter region 312 is disposed on a second thin dielectric layer 314 disposed on the back surface 306 of the substrate 302. A third thin dielectric layer 316 is disposed laterally directly between the P-type 308 and N-type 312 polycrystalline silicon emitter regions. A first conductive contact structure 318 is disposed on the P-type polycrystalline silicon emitter region 308. A second conductive contact structure 320 is disposed on the N-type polycrystalline silicon emitter region 312.

In an embodiment, an etch paste residue 399 is in a portion of an opening in which the first conductive contact structure 318 is formed. The etch paste residue 399 may remain following an imperfect cleaning process used to remove an etch paste. Accordingly, in an embodiment, etch paste residue 399 is effectively trapped between the first conductive contact structure 318 and the P-type polycrystalline silicon emitter region 308 in a final solar cell structure.

Referring again to FIG. 3, in an embodiment, the solar cell 300 further includes an insulator layer 322 disposed on the P-type polycrystalline silicon emitter region 308. The first conductive contact structure 318 is disposed through the insulator layer 322. Additionally, a portion of the N-type polycrystalline silicon emitter region 312 overlaps the insulator layer 322 but is separate from the first conductive contact structure 318. In an embodiment, an additional N-type polycrystalline silicon layer 324 is disposed on the insulator layer 322, and the first conductive contact structure 318 is disposed through the N-type polycrystalline silicon layer 324 and through the insulator layer 322, as is depicted in FIG. 3. In one such embodiment, the additional N-type polycrystalline silicon layer 324 and the N-type polycrystalline silicon emitter region 312 are formed from a same layer that is blanket deposited and then scribed to provide scribe lines 326 therein.

Referring again to FIG. 3, in an embodiment, the solar cell 300 further includes a recess 328 disposed in the back surface 306 of the substrate 302. The recess 328 is referred to as such with respect to the back surface 306 of the solar cell 300, in that the recess 329 has an uppermost surface recessed below the back surface 306. The N-type polycrystalline silicon emitter region 312 and the second thin dielectric layer 314 are disposed in the recess 328. In one such embodiment, the recess 328 has a texturized surface, and the N-type polycrystalline silicon emitter region 312 and the second thin dielectric layer 314 are conformal with the texturized surface, as is depicted in FIG. 3. In an embodiment, then, the P-type polycrystalline silicon emitter region 308 and the first thin dielectric layer 310 are disposed on a flat portion of the back surface 306 of the substrate 302, and the N-type polycrystalline silicon emitter region 312 and the second thin dielectric layer 314 are disposed on a texturized portion of the back surface 306 of the substrate, as is depicted in FIG. 3. It is to be appreciated, however, that other embodiments may not include a texturized surface, or may not include a recess altogether.

Referring again to FIG. 3, in an embodiment, the solar cell 300 further includes a fourth thin dielectric layer 330 disposed on the light-receiving surface 304 of the substrate 302. An N-type polycrystalline silicon layer 332 is disposed on the fourth thin dielectric layer 332. An anti-reflective coating (ARC) layer 334, such as a layer of silicon nitride, is disposed on the N-type polycrystalline silicon layer 332. In one such embodiment, the fourth thin dielectric layer 332 is formed by essentially the same process used to form the second thin dielectric layer 314.

In an embodiment, the substrate 302 is an N-type monocrystalline silicon substrate. In an embodiment, the first thin dielectric layer 310, the second thin dielectric layer 314 and the third thin dielectric layer 316 include silicon dioxide. However, in another embodiment, the first thin dielectric layer 310 and the second thin dielectric layer 314 include silicon dioxide, while the third thin dielectric layer 316 includes silicon nitride. In an embodiment, insulator layer 322 includes silicon dioxide.

In an embodiment, the first conductive contact structure 318 and the second conductive contact structure 320 each include an aluminum-based metal seed layer disposed on the first 308 and second 312 polycrystalline silicon emitter regions, respectively. In one embodiment, each of the first conductive contact structure 318 and the second conductive contact structure 320 further includes a metal layer, such as a copper layer or an aluminum metal foil, disposed on the aluminum-based metal seed layer.

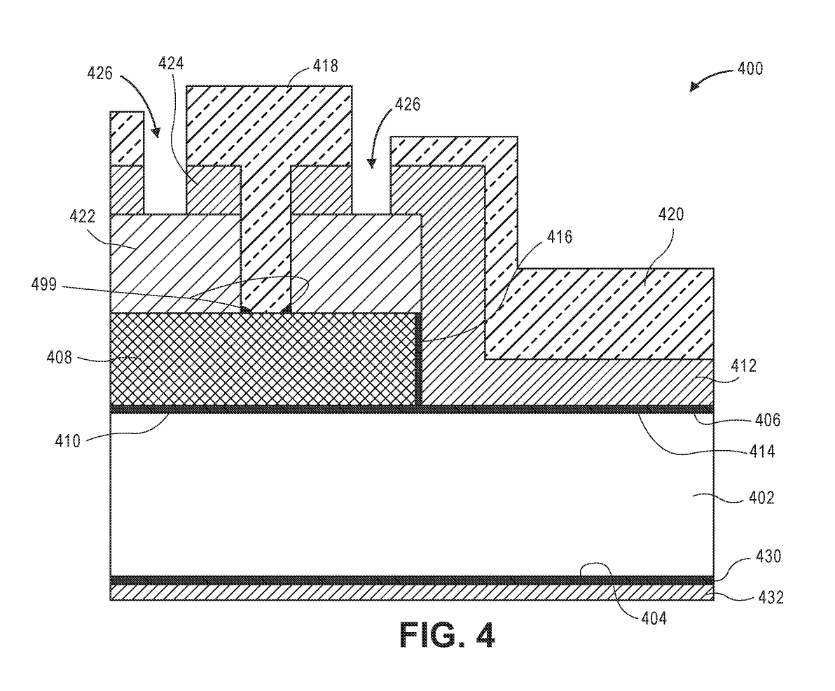

As a second exemplary solar cell, FIG. 4 illustrates a cross-sectional view of a portion of a back contact solar cell 400, in accordance with another embodiment of the present disclosure.

The solar cell 400 includes a substrate 402 having a light-receiving surface 404 and a back surface 406. A P-type polycrystalline silicon emitter region 408 is disposed on a first thin dielectric layer 410 disposed on the back surface 406 of the substrate 402. An N-type polycrystalline silicon emitter region 412 is disposed on a second thin dielectric layer 414 disposed on the back surface 406 of the substrate 402. A third thin dielectric layer 416 is disposed laterally directly between the P-type 408 and N-type 412 polycrystalline silicon emitter regions. A first conductive contact structure 418 is disposed on the P-type polycrystalline silicon emitter region 408. A second conductive contact structure 420 is disposed on the N-type polycrystalline silicon emitter region 412.

In an embodiment, an etch paste residue 499 is in a portion of an opening in which the first conductive contact structure 418 is formed. The etch paste residue 499 may remain following an imperfect cleaning process used to remove an etch paste. Accordingly, in an embodiment, etch paste residue 499 is effectively trapped between the first conductive contact structure 418 and the P-type polycrystalline silicon emitter region 408 in a final solar cell structure.

In accordance with an embodiment of the present disclosure, the first 418 and second 420 conductive contact structures each include a metal silicide layer disposed on the P-type 408 and N-type 412 polycrystalline silicon emitter regions, respectively. In one such embodiment, the metal silicide layer is formed by consuming exposed regions of the P-type 408 and N-type 412 polycrystalline silicon emitter regions in a silicidation process. As such, all exposed top surfaces of the P-type 408 and N-type 412 polycrystalline silicon emitter regions, and any other exposed silicon surfaces, are metalized, as is depicted in FIG. 4. In an embodiment, the first 418 and second 420 conductive contact structures each further includes a metal layer (such as copper) or an aluminum foil disposed on the metal silicide layer. In a particular embodiment, the metal silicide layer includes a material such as, but not limited to, titanium silicide (TiSi₂), cobalt silicide (CoSi₂), tungsten silicide (WSi₂), or nickel silicide (NiSi or NiSi₂).

Referring again to FIG. 4, in an embodiment, the solar cell 400 further includes an insulator layer 422 disposed on the P-type polycrystalline silicon emitter region 408. The first conductive contact structure 418 is disposed through the insulator layer 422. Additionally, a portion of the N-type polycrystalline silicon emitter region 412 overlaps the insulator layer 422 but is separate from the first conductive contact structure 4418. In an embodiment, an additional N-type polycrystalline silicon layer 424 is disposed on the insulator layer 422, and the first conductive contact structure 418 is disposed through the N-type polycrystalline silicon layer 424 and through the insulator layer 422, as is depicted in FIG. 4. However, in contrast to FIG. 3, the entire top surface of the N-type polycrystalline silicon layer 424 is metalized. In one such embodiment, the additional N-type polycrystalline silicon layer 424 and the N-type polycrystalline silicon emitter region 412 are formed from a same layer that is blanket deposited and then scribed to provide scribe lines 426 therein.

Referring again to FIG. 4, in an embodiment, the back surface 406 of the substrate 402 is essentially entirely flat. However, in another embodiment, the N-type polycrystalline silicon emitter region 412 and the second thin dielectric layer 414 are disposed in a recess, as was described in association with FIG. 3. In one such embodiment, the recess has a texturized surface, and the N-type polycrystalline silicon emitter region 412 and the second thin dielectric layer 414 are conformal with the texturized surface.

Referring again to FIG. 4, in an embodiment, the solar cell 400 further includes a fourth thin dielectric layer 430 disposed on the light-receiving surface 404 of the substrate 402. An N-type polycrystalline silicon layer 432 is disposed on the fourth thin dielectric layer 432. Although not depicted, in an embodiment, an anti-reflective coating (ARC) layer, such as a layer of silicon nitride, is disposed on the polycrystalline silicon layer 432. In one such embodiment, the fourth thin dielectric layer 432 is formed by essentially the same process used to form the second thin dielectric layer 414.

In an embodiment, the substrate 402, the P-type polycrystalline silicon emitter region 408, the N-type polycrystalline silicon emitter region 412 and the various dielectric layers are as described above for the substrate 302, the P-type polycrystalline silicon emitter region 308, the N-type polycrystalline silicon emitter region 312 and the various dielectric layers in association with FIG. 3.

Although certain materials are described specifically with reference to above described embodiments, some materials may be readily substituted with others with such embodiments remaining within the spirit and scope of embodiments of the present disclosure. For example, in an embodiment, a different material substrate, such as a group III-V material substrate, can be used instead of a silicon substrate. Furthermore, it is to be appreciated that, where the ordering of N+ and then P+ type doping is described specifically for emitter regions on a back surface of a solar cell, other embodiments contemplated include the opposite ordering of conductivity type, e.g., P+ and then N+ type doping, respectively. In other embodiments, a P-type doped substrate is used in place of an N-type doped substrate. In other embodiments, a doping window used to dope the substrate is a relatively large doping window. Additionally, although reference is made significantly to back contact solar cell arrangements, it is to be appreciated that approaches described herein may have application to front contact solar cells as well. In other embodiments, the above described approaches can be applicable to manufacturing of other than solar cells. For example, manufacturing of light emitting diode (LEDs) may benefit from approaches described herein.

Furthermore, in an embodiment, a cluster chemical vapor deposition (CVD) tool can be used to combine many of the above described process operations in a single pass in a process tool. For example, in one such embodiment, up to four distinct CVD operations and an RTP operation can be performed in a single pass in a cluster tool. The CVD operations can includes depositions of layers such as the above described back side P+ polysilicon layer, both front and back side N+ polysilicon layers, and the ARC layer. In one embodiment, the cluster CVD tool is a cluster plasma enhanced chemical vapor deposition (PECVD) tool.

Thus, methods of fabricating solar cell emitter regions with differentiated P-type and N-type region architectures fabricated using an etch paste, and the resulting solar cells, have been disclosed.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A method of fabricating a solar cell, the method comprising:
forming a first polycrystalline silicon layer above a substrate;
forming an insulating cap on the first polycrystalline silicon layer;
forming a second polycrystalline silicon layer on the insulating cap;
forming an insulating layer on the second polycrystalline silicon layer;
laser ablating a portion of the insulating layer and a portion of the second polycrystalline silicon layer to form an opening exposing a portion of the insulating cap on the first polycrystalline silicon layer;
removing the exposed portion of the insulating cap with an etch paste to extend the opening and expose a portion of the first polycrystalline silicon layer; and
subsequent to removing the exposed portion of the insulating cap with the etch paste, cleaning the extended opening by removing residual etch paste.

2. The method of claim 1, further comprising:
forming a conductive contact structure in the extended opening, the conductive contact structure electrically connected to the first polycrystalline silicon layer.

3. The method of claim 1, wherein removing the exposed portions of the insulating cap with the etch paste comprises using a hydrofluoric acid (HF) based etch paste or a phosphoric acid (H₃PO₄) based paste.

4. The method of claim 1, wherein the second polycrystalline silicon layer has a thickness of approximately 200-500 Angstroms, and the insulating layer has a thickness of approximately 500-2000 Angstroms, and wherein laser ablating the portion of the insulating layer and the portion of the second polycrystalline silicon layer comprises laser ablating with a green laser.

5. A solar cell fabricated according to the method of claim 1.

6. A method of fabricating a solar cell, the method comprising:
forming a plurality of P-type polycrystalline silicon regions on a first thin dielectric layer on a back surface of an N-type semiconductor substrate, the N-type semiconductor substrate having a light-receiving surface opposite the back surface;
forming an insulating cap on the P-type polycrystalline silicon regions;
forming a plurality of N-type polycrystalline silicon regions on a second thin dielectric layer formed in a corresponding one of a plurality of trenches interleaving the plurality of P-type polycrystalline silicon regions in the back surface of the P-type semiconductor substrate, wherein a portion of the plurality of N-type polycrystalline silicon regions overlaps the insulating cap on the P-type polycrystalline silicon regions;
forming an insulating layer on the plurality of N-type polycrystalline silicon regions;
laser ablating a portion of the insulating layer and a portion of the plurality of N-type polycrystalline silicon regions to expose a portion of the insulating cap on the P-type polycrystalline silicon regions;
removing the exposed portions of the insulating cap with an etch paste to expose a portion of the P-type polycrystalline silicon regions; and
forming a plurality of conductive contact structures electrically connected to the P-type polycrystalline silicon regions and the N-type polycrystalline silicon regions.

7. The method of claim 6, wherein removing the exposed portions of the insulating cap with the etch paste comprises using a hydrofluoric acid (HF) based etch paste or a phosphoric acid (H₃PO₄) based paste.

8. The method of claim 6, wherein each of the plurality of N-type polycrystalline silicon regions has a thickness of approximately 200-500 Angstroms, and the insulating layer has a thickness of approximately 500-2000 Angstroms.

9. The method of claim 8, wherein laser ablating the portion of the insulating layer and the portion of the plurality of N-type polycrystalline silicon regions comprises laser ablating with a green laser.

10. The method of claim 6, wherein each of the plurality of trenches is formed having a texturized surface.

11. The method of claim 6, further comprising:
forming a third thin dielectric layer laterally directly between adjacent ones of the P-type polycrystalline silicon regions and the N-type polycrystalline silicon regions.

12. A solar cell fabricated according to the method of claim 6.

13. A solar cell, comprising:
an N-type semiconductor substrate having a light-receiving surface and a back surface;
a plurality of P-type polycrystalline silicon regions disposed on a first thin dielectric layer disposed on the back surface of the N-type semiconductor substrate;
a plurality of N-type polycrystalline silicon regions disposed on a second thin dielectric layer disposed in a corresponding one of a plurality of trenches interleaving the plurality of P-type polycrystalline silicon regions in the back surface of the P-type semiconductor substrate; and
a plurality of conductive contact structures electrically connected to the P-type polycrystalline silicon regions and the N-type polycrystalline silicon regions, wherein an etch paste residue is between at least one of the plurality of conductive contact structures and a corresponding one of the plurality of P-type polycrystalline silicon regions.

14. The solar cell of claim 13, wherein the etch paste residue comprises fluorine (F).

15. The solar cell of claim 13, wherein the plurality of N-type polycrystalline silicon regions overlap a portion of the plurality of P-type polycrystalline silicon regions.

16. The solar cell of claim 13, wherein each of the plurality of P-type polycrystalline silicon regions and each of the plurality of N-type polycrystalline silicon regions have a same thickness.

17. The solar cell of claim 13, wherein the thickness is approximately 200-500 Angstroms.

18. The solar cell of claim 13, wherein each of the plurality of trenches has a depth approximately in the range of 0.1-3 microns from the back surface and into the N-type semiconductor substrate.

19. The solar cell of claim 13, wherein each of the plurality of trenches has a texturized surface.

20. The solar cell of claim 13, further comprising:
a third thin dielectric layer disposed laterally directly between adjacent ones of the P-type polycrystalline silicon regions and the N-type polycrystalline silicon regions.
